(19) United States
(12) Patent Application Publication
(10) Pub. No.: US 2002/0036301 A1
(43) Pub. Date: Mar. 28, 2002

(54) Semiconductor integrated circuit device

(75) Inventors: Katsushi Nagaba, Tokyo (JP); Shigeo Ohshima, Yokohama-shi (JP)

Correspondence Address: HOGAN & HARTSON L.L.P., 500 S. GRAND AVENUE, SUITE 1900, LOS ANGELES, CA, 90071-2611, US

(73) Assignee: KABUSHIKI KAISHA TOSHIBA

(21) Appl. No.: 09/965,534

(22) Filed: Sep. 25, 2001

(30) Foreign Application Priority Data
Sep. 28, 2000 (JP) 2000-297703

(51) Int. Cl. H01L 31/0336

(52) U.S. Cl. 257/200

(57) ABSTRACT

A semiconductor integrated circuit device comprises a register circuit receives a data signal, a delay adjustment circuit receives an output of the register circuit and a driver circuit receives an output of the delay adjustment circuit. An output timing of the register circuit is controlled by a clock signal. A delay time of the delay adjustment circuit is adjusted by a delay adjustment signal based on the data signal.

### BACKGROUND OF THE INVENTION

1. Field of the Invention

The present invention relates to a semiconductor integrated circuit device, and, more particularly, to a timing control of the data output.

2. Description of the Related Art

FIG. 14 is a block diagram showing a read path in a general semiconductor memory chip.

As shown in FIG. 14, the read data RD (RDn) which read from a memory cell (not shown) is input to the first-in-and-first-out type register circuit (hereinafter referred to as FIFO) 101. The FIFO 101 operates in synchronization with read data output clock OUTCLK. When the clock OUTCLK will become, for example, to the “HIGH” level, the input read data RD is output as data QR (QRn).

The data QR is input to an off-chip driver circuit (hereinafter referred to as OCD) 102. The OCD 102 operates, for example, on the basis of a high impedance signal HIZ (not shown). Then, when the high impedance signal HIZ is “LOW” level, for example, the input data QR is output as the read data DQ (DQn) to drive an external bus (not shown) connected to an external pin via a pad and a lead frame. On the contrary, when a signal HIZ is set to the “HIGH” level, the OCD 102 becomes a high impedance state.

In the above read path, the read number of the data lines RD and the number of the data lines QR are respectively provided so as to correspond to a bit constitution. For example, in the case where the bit constitution is “×4 bits”, four read data lines RD and four data lines QR are provided respectively. In this case, 2⁴=16 combinations from [0000] to [1111] are present as the data pattern of the read data. It goes without saying that when the bit constitution increases from “×8 bits” to “×16 bits, the combination of the data pattern also increases as well.

By the way, it is generally known that the access time of data is dispersed with the combination of the data pattern. The cause of this dispersion can be cited as the following three points (1) to (3).

(1) A resistance R, the capacitance C and the impedance L of the data path from the memory cell to the external pin are not equivalent in respective bit. Consequently, the time constant of the data path is dispersed for each bit.

FIG. 15A is a block diagram of an LSI product incorporating a semiconductor memory chip. FIG. 15B is an equivalent circuit diagram thereof.

As shown in FIGS. 15A and 15B, for example, the QRa and QRb is different from each other in length of the data line QR from FIFO 101 to the OCD 102. In a similar manner, the length of the lead frame QL from the pad to the external pin is different from each other in QLa and QLb. An example of the relation ship between the capacitance and the resistance of the data line QR, and the inductance of the lead frame QL is described hereinbelow.

Ca>Cb

Ra>Rb

La>Lb

Here, symbols Ca and Ra denote the capacitance and the resistance of the data line Qra, respectively. Symbols Cb and Rb denote the capacitance and the resistance of the data line QRb respectively. Symbol La denotes the inductance of the lead frame QLa and symbol Lb denotes the inductance of the lead frame QLb.

From such relation, the access time Ta of the read data DQa becomes larger than the access time Tb of the read data DQb.

(2) n bit wiring (the read data line RD and the data line QR) is layout, in the chip, generally in parallel to each other. Consequently, the electric load capacitance stored in the capacitance (hereinafter referred to as adjacent capacitances) between adjacent wirings differs in the data pattern. As the result of that the electric load capacitance stored in the adjacent capacitances is different, the data transmission time is not always constant, and is dispersed for each data pattern.

FIG. 16A is a view showing a three bit wiring which run in parallel to each other. FIG. 16B is a view showing adjacent capacitance respectively.

On the periphery of the wiring 1 shown in FIG. 16A, as shown in FIG. 16B, three adjacent capacitances are mainly located. The first is an adjacent capacitance Cl between the wiring 1, and other wiring located under this wiring 1, or the semiconductor substrate. The second is the adjacent capacitance C12 between the wiring 1, and a wiring 2 located beside the wiring 1 and the third is the adjacent capacitance c13 between the wiring 1 and the wiring 3 besides the wiring 1.

FIG. 16C is a view showing a relation between the potential change of three bit wirings 1, 2, and 3 and the data pattern.

As shown in FIG. 16C, the data pattern is divided into two modes; an “in-phase” and a “reverse phase”. The “in-phase” refers to a case in which the potential of the wirings 1, 2, and 3 rise together, or fall together. Furthermore, the “reverse phase” refers to a case in which the potential of the wiring 1 changed in a manner reverse to at least one of the potentials of the wirings 2 and 3.

FIG. 16D is a view showing a relation between the data pattern of the data transmission time. In FIG. 16D, there is shown the potential change waveform at the end portion B point of the wiring at the time when the point A of the wiring 1 changes from the “LOW” level to the “HIGH” level.

As shown in FIG. 16D, when the wirings 2 and 3 changes from the “LOW” level to the “HIGH” level in the same manner as the wiring 1 (in-phase), no potential difference is present at both ends of the adjacent capacitances C12 and C13. As a consequence, it is possible to consider that the adjacent capacitance of the wiring 1 is equal only to the adjacent capacitance C1. That is, the wiring capacitance is set to a small state, and the data transmission time is fast.

In contrast, when the wirings 2 and 3 change from the “HIGH” level to the “LOW” level in a reverse manner (reverse phase), a potential difference is present at both ends of the adjacent capacitances C12 and C13. As a consequence, it is possible to consider that the wiring capacitance of the wiring 1 is set to C1+C12+C13, the result that the wiring capacitance becomes large as compared with the case of the “in-phase”. Consequently, the data transmission time becomes slow.

Incidentally, not shown in FIG. 16D, it goes without saying that when one of the wirings 2 and 3 has the in-phase with the wiring 1 when the other of the wirings 2 and 3 has the reverse phase, the transmission time is present between the “in-phase” and the “reverse phase”.

Furthermore, in FIG. 16D, there is shown a case in which the wiring 1 changes from the “LOW” level to the “HIGH” level. In contrast, even in the case where the wiring 1 changes from the “HIGH” level to the “LOW” level, the relation between the adjacent capacitance and the transmission time is similar.

Along with the miniaturization and higher integration of the semiconductor memory chip every year, there is a tendency that the width of the wiring, and a gap between the wirings are narrowed down, and ratio occupied by the adjacent capacitance in the wiring capacitance increases. As a consequence, it is assumed that the disparity in the transmission time becomes conspicuous from now on.

(3) The power source voltage is used for the output for the simultaneous power “on” of a large number of OCDs 102 is oscillated (hereninafter referred to as power source noise). As a consequence, the data access time is scattered on the large number side and the small number side of the data “HIGH” (or “1”) and “LOW” (or “0”).

FIG. 17 is a view showing a general OCD structure.

As shown in FIG. 17, a large number of OCD 102 (102-1 to 102-n), a high potential power source wiring VDDQ for the output and a low potential power source wiring VSSQ for the output are arranged, and which are connected to the outside power source and the outside bus provided on the outside of the package via the lead frame (load), respectively.

The power source noise is generated because the transient current which the transistor constituting the OCD 102 flows induces a voltage with an inductance of the package (power source).

Generally, the power source noise ΔV can be represented in the following simple expression.

ΔV=N•Leff•(di/dt)

Here, symbol N denotes a number of simultaneous switching of OCD 102, symbol Leff denotes an effective inductance of the package, and symbol di/dt denotes a current drive performance of OCD 102.

In FIG. 17, there is shown a state in which the OCD 102-1 changes from the “LOW” level to the “HIGH” level for one bit, and all the other OCD 102-2 to 102-n changes from the “HIGH” level to the “LOW” level.

As shown in FIG. 17, in the case where a large number of bits changes from the “HIGH” level to the “LOW” level, a voltage is induced with the transient current which the NMOS transistor constituting the OCD 102-2 to OCD102-n flows and the inductance of the package so that a noise is generated in the power source wiring VSSQ. As a consequence, the NMOS transistor cannot obtain a sufficient voltage VGS between the gate and the source so that access of data becomes slow. Meanwhile, the PMOS transistor constituting OCD102-0 can obtain a sufficient voltage VGS between the gate and the source so that access of data becomes fast on the contrary.

In this manner, since the number N of OCD 102 which is simultaneously turned on with the data pattern differs, the power source noise ΔV is generated and the access time is scattered.

When the bit constitution further increases, the number of OCDs 102 also increases. When the number of OCDs 102 increases, the power source noise AV is enlarged and the disparity in the access time further increases.

FIG. 18 is a view showing a relation between the data pattern and the data access time with respect to the above points. A line I shown in FIG. 18 represent data access time which changes from the “LOW” level to the “HIGH” level. A line II on the contrary represents data access time which changes from the “HIGH” level to the “LOW” level.

As shown in FIG. 18, the disparity of the access time becomes maximum at the time of one bit reverse phase.

In recent years, in the semiconductor memory which operates in synchronization with the clock, the specification of the access time invites an increase in the chip which does not satisfy the fact that the time is about ±1 ns with respect to the outside clock, or a reduction in a margin so that an unfavorable influence is exerted, for example, upon the yield ratio.

Furthermore, it is thought that when an operation of a semiconductor memory or a system using this semiconductor memory is further heightened in speed, it is assumed that the specification of the access time becomes more strict, and it becomes not easy to satisfy this specification.

### BRIEF SUMMARY OF THE INVENTION

A semiconductor integrated circuit device according to an embodiment of the present invention comprises: a register circuit which receives a data signal, an output timing of the register circuit being controlled by a clock signal; a delay adjustment circuit which receives an output of the register circuit, a delay time of the delay adjustment circuit being adjusted by a delay adjustment signal based on the data signal; and a driver circuit which receives an output of the delay adjustment circuit.

### BRIEF DESCRIPTION OF THE SEVERAL VIEWS OF THE DRAWING

FIG. 1 is a block diagram showing a read path in a semiconductor memory chip according to a first embodiment of the present invention.

FIG. 2 is a circuit diagram showing one example of a circuit of a FIFO.

FIG. 3 is a block diagram showing one configuration example of a DELAY.

FIG. 4 is a circuit diagram showing one circuit example of the DELAY.

FIG. 5 is a circuit diagram showing one circuit example of a DEC.

FIG. 6 is a circuit diagram showing one circuit example of a DEC in the “×4 bits”.

FIG. 7 is a circuit diagram showing one circuit example of an OCD.

FIG. 8 is a view showing an effect of a first embodiment of the present invention.

FIG. 9 is a circuit diagram showing a variant example of the DELAY.

FIG. 10 is a circuit diagram showing a first variant example of the DEC.

FIGS. 11A, 11B and 11C are circuit diagrams showing second variant examples of the DEC respectively.

FIG. 12 is a block diagram showing a read path in the semiconductor memory chip according to a second embodiment of the present invention.

FIG. 13 is a block diagram showing a read path in the semiconductor memory chip according to a third embodiment of the present invention.

FIG. 14 is a block diagram showing a read path in a general semiconductor memory chip.

FIG. 15A is a block diagram showing an LSI product incorporating a semiconductor chip.

FIG. 15B is an equivalent circuit diagram thereof.

FIG. 16A is a view showing 3 bit wirings which run in parallel to each other.

FIG. 16B is a view showing an adjacent capacitance of three bit wirings which run in parallel to each other.

FIG. 16C is a view showing a relation between potential change of the three bit wirings which run in parallel to each other and the data pattern.

FIG. 16D is a view showing a relation between the potential at point A and the potential at point B.

FIG. 17 is a view showing a general OCD structure.

FIG. 18 is a view showing a relation between the data pattern and the data access time.

### DETAILED DESCRIPTION OF THE INVENTION

Hereinafter, embodiments of the present invention will be explained by referring to the drawings. In this explanation, common portions are denoted by common reference numerals over all the drawings.

First Embodiment

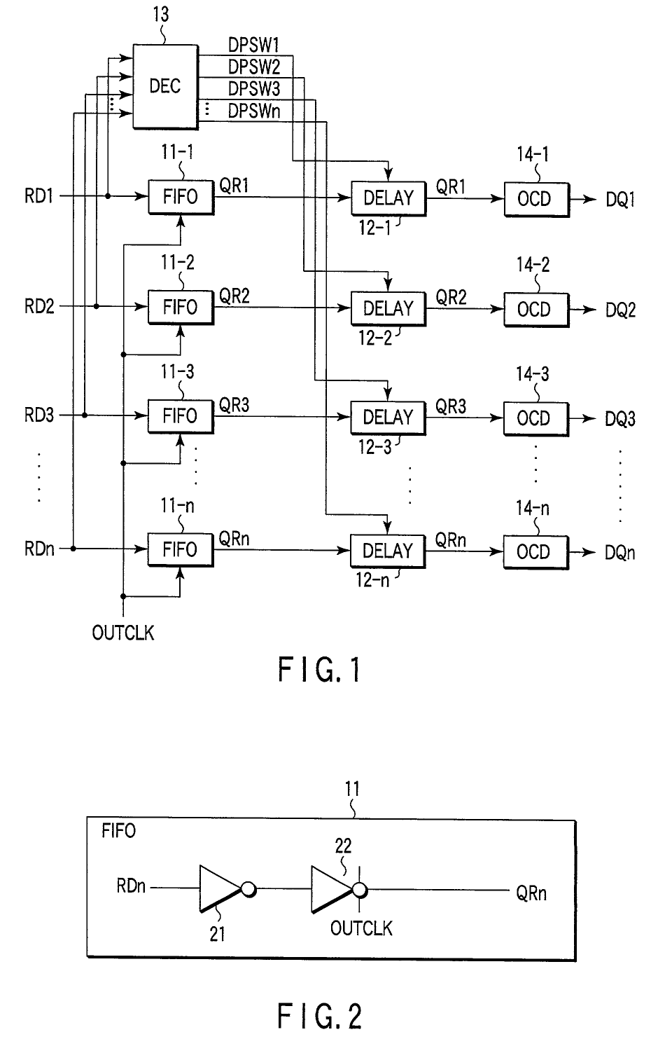

FIG. 1 is a block diagram showing a basic structure of a read path in the semiconductor memory chip according to a first embodiment of the present invention.

As shown in FIG. 1, the n bit read data RD (RD1 to RDn) read from the memory cell not shown is input to the first- in-first-out type register circuit (hereinafter referred to as FIFO) 11 (11-1 to 11-n) respectively. The FIFO 11 operates in synchronization with the read data output clock OUTCLK. When the clock OUTCLK I is set to, for example, “HIGH” level, the input read data RD is output as the data QR(QR1 to QRn). One circuit example of the FIFO 11 is shown in FIG. 2.

As shown in FIG. 2, the FIFO11 comprises, for example, an inverter 21, and a clocked inverter 22. The read data RD is input to the clocked inverter 22 via the inverter 21. The read data RD is input to the clocked inverter 22 via the inverter 22. When the clock OUCLK is set to “HIGH”, the clocked inverter 22 outputs the read data RD in synchronization with the clock OUTCLK.

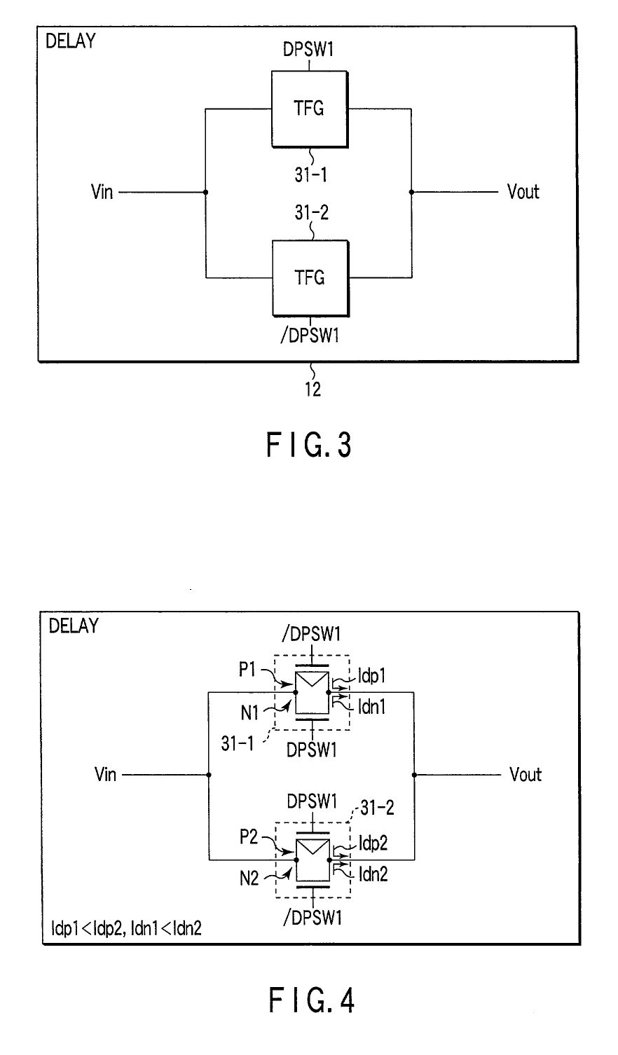

The data QR is input to the delay adjustment circuit (hereinafter referred to as DELAY) 12 (12-1 to 12-n). The DELAY 12 delays the data QR in accordance with the delay adjustment signal DPSW (DPSW1 to DPSWn). One structure example of the DELAY 12 is shown in FIG. 3.

As shown in FIG. 3, the DELAY 12 comprises two transfer gates (hereinafter referred to TFG) 31 (31-1, 31-2) mutually connected in parallel, for example, between the input terminal Vin and the output terminal Vout. Detailed one circuit example of the DELAY 12 is shown in FIG. 4.

As shown in FIG. 4, TFG31-1 comprises, for example, PMOS P1 and PMOS N1 mutually connected in parallel between the input terminal Vin and the output terminal Vout. The TFG 31-2 comprises PMOS P2 and NMOS N2 mutually connected in parallel between the input terminal Vin and the output terminal Vout. To the gate of the PMOS P1, a delay adjustment signal DPSW (DPSWn) is input and to the gate of the NMOS N1 a reverse signal/DPSW (/DPSWn) of a signal DPSW is input. Furthermore, to the gate of the PMOS P2 the reverse signal/DPSW is input and to the gate of the NMOS N2 a signal DPSW is input. As a consequence, one of the TFG 31-1 and 31-2 is turned on in accordance with the level of the signal DPSW.

In a circuit shown in FIG. 4, the relation between the drive current Idp1 of the PMOS P1 and the drive current Idp2 of the PMOS P2 is set in the following manner.

Idp1<Idp2

In the same manner, the relation between the drive current Idn1 of the NMOS N1 and the drive current Idn2 of the NMOS N2 is set in the following manner.

Idn1<dp2

From this relation, when the TFG31-1 is turned on, the delay time of the DELAY 12 is enlarged. on the other hand, when the TFG 31-2 is turned on, the delay time of the DELAY 12 is decreased.

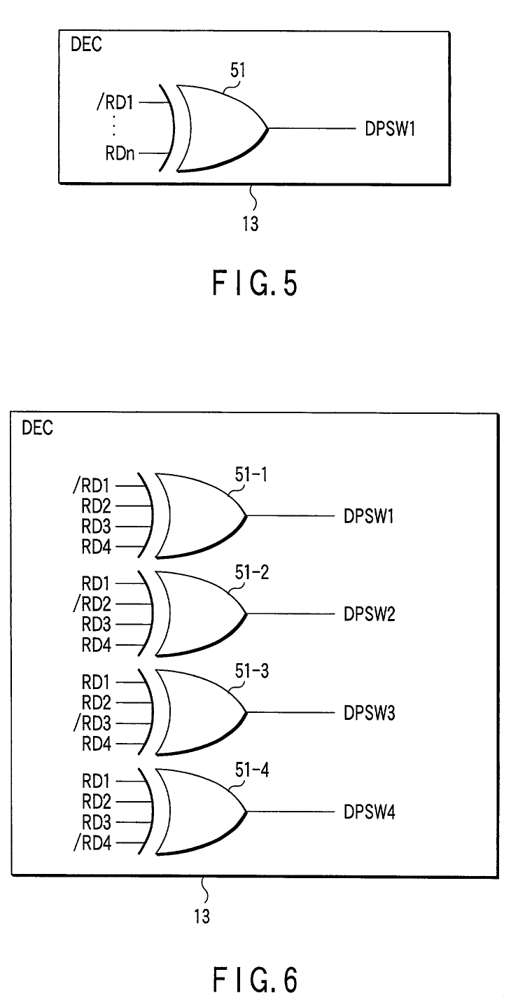

It is determined from the delay adjustment signal DPSW as to whether or not the delay time is enlarged. The delay adjustment signal DPSW is output from the decode circuit (hereinafter referred to as DEC) 13. The DEC 13 decodes the read data RD1 to RDn to output the delay adjustment signal DPSW. One example of the circuit of the DEC 13 is shown in FIG. 5.

As shown in FIG. 5, the DEC comprises an exclusive AND circuit (hereinafter referred to as EXOR) 51. To the EXOR 51, the data pattern of the read data which is desired to be detected is input. With respect to this, for example, there will be explained a case in which the bit constitution of the read data RD is ×4 bits (RD1 to RD4).

FIG. 6 is a circuit diagram showing one circuit example of the DEC 13 in the ×4 bits.

As shown in FIG. 6, when it is desired to detect whether or not only RD1 out of the read data RD1 to RD4 has the reverse phase, ″/RD4, /RD3, /RD2, /RD1 or ″RD4, RD3, RD2 and RD1″ is input to EXOR 51-1.

By doing so, when the data pattern is “0001” or “1110”, the EXOR 51-1 outputs a delay adjustment signal DPSW 1 =“HIGH”.

The DELAY 12-1 receives the delay adjustment signal DPSW1=“HIGH” to enlarge the delay of the data QR1 (corresponding to the RD1) as compared with the other data QR2 through QR4 (respectively corresponding to RD2 to RD4) to transmit the delay to the off-chip driver circuit (hereinafter OCD) 14-1.

Furthermore, when it is desired to detect whether or not only RD2 has the reverse phase out of the read data RD1 through RD4, ″/RD4, /RD3, /RD2, /RDI or ″RD4, RD3, RD2 and RD1″ are input. By doing do, when the data pattern is “00101” or “1101”, the EXOR 51-2 outputs the delay adjustment signal DPSW2 =“HIGH”.

Consequently, the DELAY 1-2 receives the DPSW2 =“HIGH”, the DELAY 12-2 receives the delay adjustment signal DPSW 2 =“HIGH”, the delay of the data QR2 is enlarged as compared with other data QR1, QR3 and QR4 to be transmitted to the OCD 14-2.

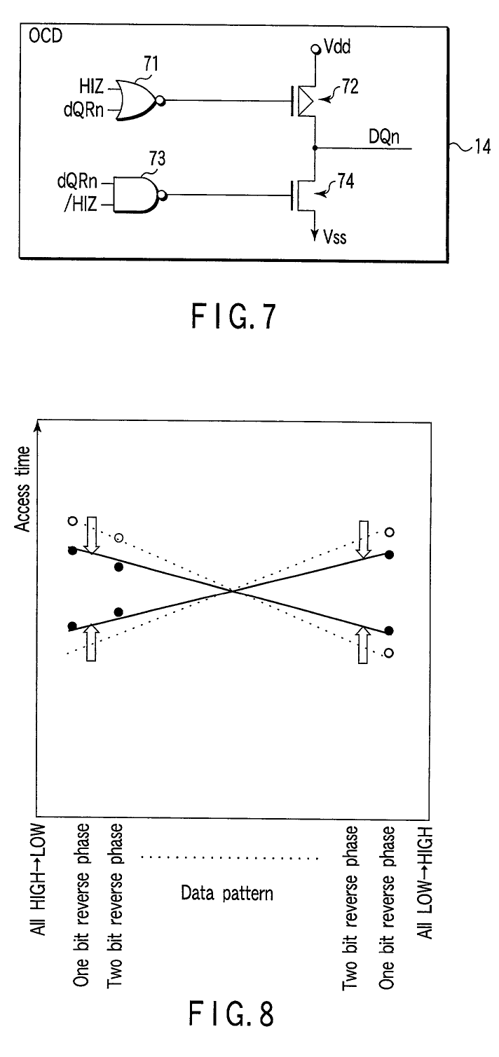

The OCD 14 is operated, for example, on the basis of the high impedance signal HIZ. When the signal HIZ is set to the “LOW” level, the OCD 14 outputs the data QR4 which is delay adjusted as data DQ (DQn) to drive the an outside bus connected to the external pin. On the contrary, when the signal HIZ is set to a “HIGH” level, the OCD 14 is set to the high impedance state. FIG. 7 is a view showing an example of the circuit of the OCD 14.

As shown in FIG. 7, the OCD 14 comprises a denial logical OR circuit (hereinafter referred to as NOR) 71, a PMOS 72 for receiving an output of the NOR 71, a denial logical AND circuit (hereinafter referred to as NAND) 73, and NMOS 74 for receiving an output of the NAND 73. The data QR which is delay adjusted is input respectively to the NOR 71 and NAND 73.

When the high impedance signal HIZ is set to the “LOW” level (the reverse high impedance signal bHIZ is set to the “HIGH” level), both the NOR 71 and the NAND 73 are turned on. As a consequence, the output (DQ) of the OCD 14 changes in accordance with the level of the data QR which is delayed and adjusted.

On the contrary, when the high impedance signal HIZ is set to the “HIGH” level (the reverse high impedance signal b HIZ is set to the “LOW” level), the NOR 31 and the NAND 73 fixes the respective outputs to the “HIGH” level and the “LOW” level respectively irrespective of the data OR level which is delayed and adjusted. As a consequence, the OCD 14 is set to the high impedance state.

In the case of the device according to the first embodiment, it is detected, for example, only the one bit has the reverse phase or not, out of the n bits read data RD1 to RDn. Furthermore, on the basis of the result of the detection, for example, the read data which is detected that only one bit has the reverse phase is delayed with the DELAY 12. As a consequence, as shown in FIG. 8, a time difference between the access time of the reverse phase bit and the access time of the other bits can be shrunken.

In this manner, in the device according to the first embodiment, at the time of the one bit reverse phase in which the disparity of the access time becomes maximum, the disparity of the access time can be small, so that the disparity in the access time resulting from the test pattern can be alleviated.

Incidentally, respective delay times of the DELAY 12-1 to 12-n may be set to the same level. When it is possible to attain the purpose of alleviating the disparity in the access time resulting from the data pattern, it is possible to set a delay time difference for each of the DELAY 12-1 to 12-n, or an optimal delay time.

One Variant Example of Delay Adjustment Circuit

Next, there will be explained a variant example of the DELAY 12.

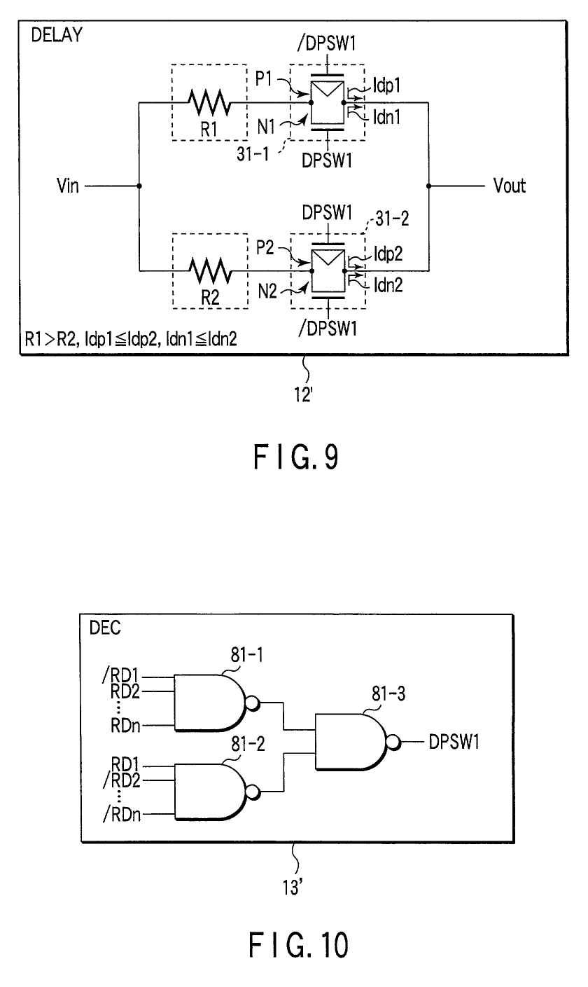

FIG. 9 is a circuit diagram showing a variant example of the DELAY 12.

As shown in FIG. 9, in the example of the DELAY 12′ according to the variant example, resistors R1 and R2 are connected in series, in between input terminal Vin and TFG 31-1 and, between input terminal Vin and TFG 31-2. In this case, the delay time is determined with the resistors R1 and R2, and the ON resistance of RFG31-1 and TFG31-2.

In this variant example, the resistance values of the resistors R1 and R2 are set in the following manner.

R1>R2

In this case, the drive currents Idp1, dp2, Idn1 and Idn2 can be set in the following manner.

Idp1≦Idp2

Idn1≦Idn2

In such DELAY 12′, the same operation as the DELAY 12 shown in FIG. 4 can be conducted.

Incidentally, in this variant example, the resistors R1 and R2 may be changed to the delay circuit using, for example, the inverter circuit.

Furthermore, TFG31-1 and TFG 31-2 may be changed to the inverter circuit in which an operation is enabled, for example, with the delay adjustment signal DPSW. This change is not limited to the variant example, and may be made in the above embodiment.

First Variant Example of the Decode Circuit

Next, a first variant example of the DEC13 will be explained.

FIG. 10 is a circuit diagram showing a first variant example of the DEC 13.

As shown in FIG. 10, the DEC13′ according to the first variant is constituted by using three denial NAND circuits 81-1 to 81-3.

In the DEC 13′ shown in such FIG. 10, the operation same as DEC 13 shown in FIG. 5 can be conducted.

Second Variant Example of the Decode Circuit

Next, a second variant of the DEC 13 will be explained.

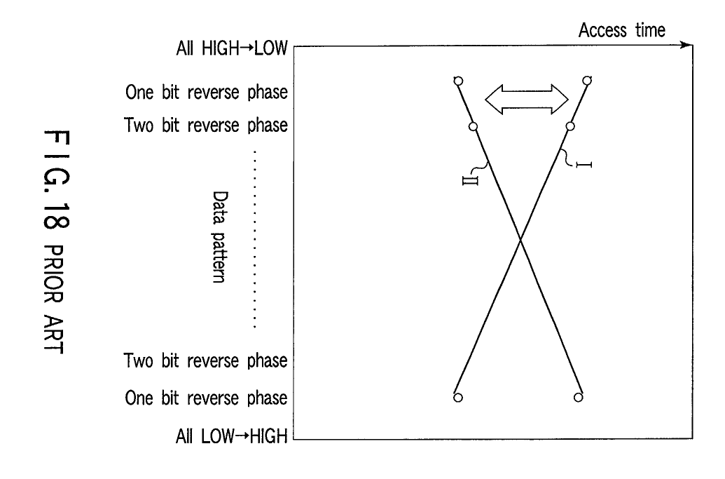

As has been explained in the section on the prior art by referring to FIG. 18, the data skew is maximum at the time of one bit reverse phase, and the data skew is decreased in accordance with an increase in the reverse phase bit.

However, when data skew is still large and the specification of the access time is not satisfied only by saving one bit reverse time, it becomes necessary to detect the data pattern having a large reverse phase bit number.

However, the number of data patterns having a large number of reverse phase bits abruptly increases with an increase in the bit constitution. For example, the data pattern which becomes one bit or two bit reverse phase is set to “×8 bits” there are available 36 patterns. In the case of the “×16 bits, the data pattern increases to 136 patterns. Furthermore, when the bit constitution increases, the data pattern which becomes one bit or two bits reverse phase further increases.

When an attempt is made to detect the data pattern with the DEC 13 shown in FIG. 6 and with the DEC 13′, the circuit scale is largely increased.

An object of the DEC 13″ according to the second variant example is to detect the data pattern having a large number of reverse phase bit number with a small scale circuit.

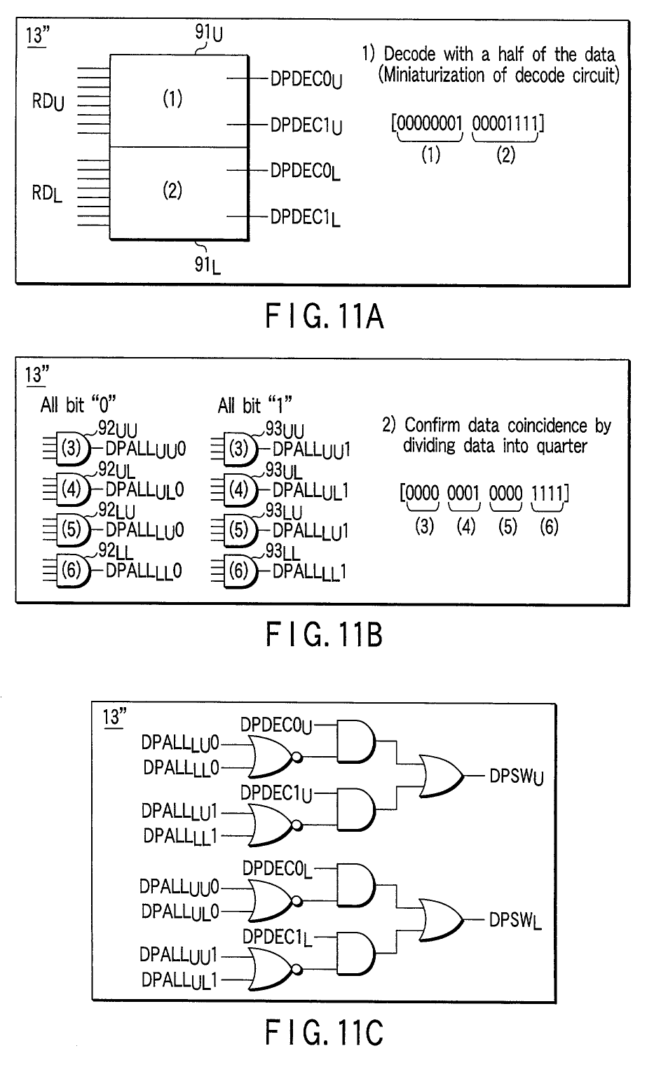

FIGS. 11A to 11C are circuit diagrams showing a second variant example of the DEC 13.

In the DEC 13″ according to the second variant example, the data pattern is detected by dividing the n bit read data RD1 for RDn into two half portions, for example, upper bits (RD_{U}) and lower bits (RD_{L}) in circuits 91_{U}, 91_{L} shown in FIG. 11A. Output signals of each of the decode circuits 91_{U} and 91_{L} are set to DPDECO_{U}/1_{U}/O_{L}/1_{L} respectively. The read data is divided depending upon whether or not the reverse data is “0” or “1”.

Furthermore, in the circuits ⁹²_{UU}, 92_{UL}, 92_{LU}, 93_{UU}, 93_{UL}, 93_{LU}, and 93_{LL}, shown in FIG. 11B, it is judged whether or not all the bits are agreed either at “0” or at “1” within further half bits of the upper place bits (RD_{U})/lower place bits (RD_{L}). The output signals are respectively set to DPALL_{UU}0/_{UU}1/_{UL}0/_{UL}1/_{LU}0/_{LU}1/_{LL}0/_{LL}1.

Furthermore, in the circuit shown in FIG. 11C, the delay adjustment signal DPSW_{U} on the side of the upper place bit (RD_{U}) and the delay adjustment signal DPSW_{L} on the side of the lower place bit (RD_{L}) are output respectively.

When the Reverse Data is “0” and the Output Signal DPDECO_{U} is “HIGH”)

When DPALL_{LU}0 or DPALL_{LL}0 is “LOW”, it is judged that the whole “1” is small, and the delay adjustment DPSW_{U} becomes “HIGH”.

On the contrary, when the lower place bit DPALL_{LU}0 or DPALL_{LL}0 is “HIGH”, it is judged that the whole “1” is large in number, so that the delay adjustment signal DPSWU becomes “LOW”.

When the Reverse Data is“1” and the Output Signal DPDECO1_{U} is “HIGH”)

When the upper place bit DPALL_{LU}1 or DPALL _{LL}1 is “LOW”, it is judged that the whole “1” is few in number, and the delay adjustment signal DPSW_{U} becomes “HIGH”.

On the contrary, when the lower place bit DPALL_{LU}1 or DPALL_{LL}1 is set to the “HIGH” level, it is judged that the whole “1” is large in number, and the delay adjustment signal DPSWu becomes “LOW”.

When reverse data is “0” and the Output Signal DPDECO_{L} is “HIGH”)

When the upper place bits DPALL_{UU}0 or DPALL_{UL} is “HIGH”, it is judged that whole “0” is small in number, and the delay adjustment signal DPSW_{L}0 becomes “LOW”.

On the contrary, when the upper place bit DPALL_{UU}0 or DPALL_{UL}0 is “HIGH”, it is judged that the whole “0” is large in number, and the delay adjustment signal DPSW_{L} becomes “LOW”.

When reverse Data is “1” and the Output Signal is “HIGH”)

When the lower place bits DPALL_{UU}1 or DPALL_{UL}0 is “LOW”, it is judged that the whole “1” is small in number, and the delay adjustment signal DPSW_{L} becomes “HIGH”.

On the contrary, when the lower place bits DPALL_{UU}1 or DPALL_{UL}0 is “HIGH”, it is judged that the whole “1” is small in number, and the delay adjustment signal DPSWL becomes “LOW”.

As has been explained, the DEC 13″ according to the second variant example of the present invention may be constituted of one 2^{n/2-th} true value table as compared with the above DEC 13 and DEC 13′ so that the DEC 13″ is more effective when the bit constitution is larger in number.

Second Embodiment

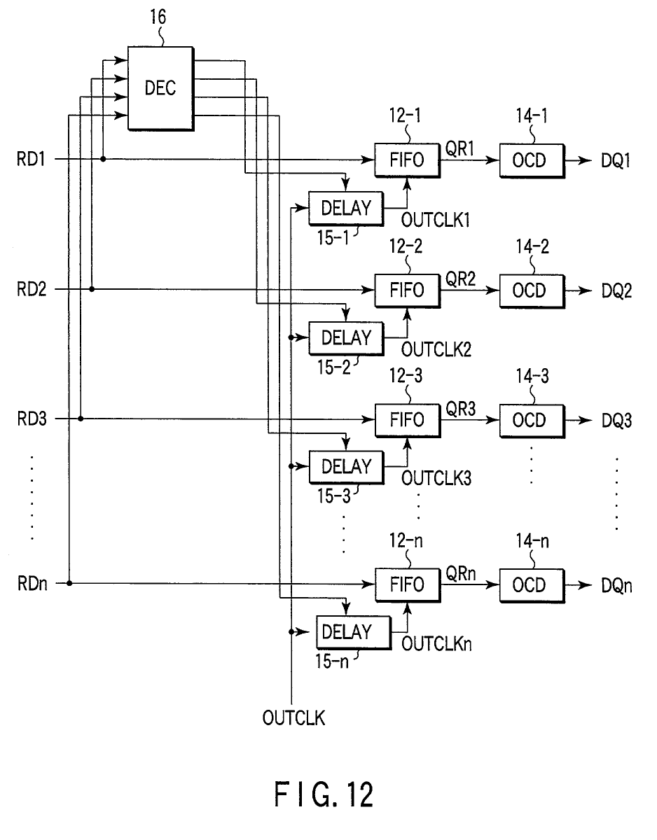

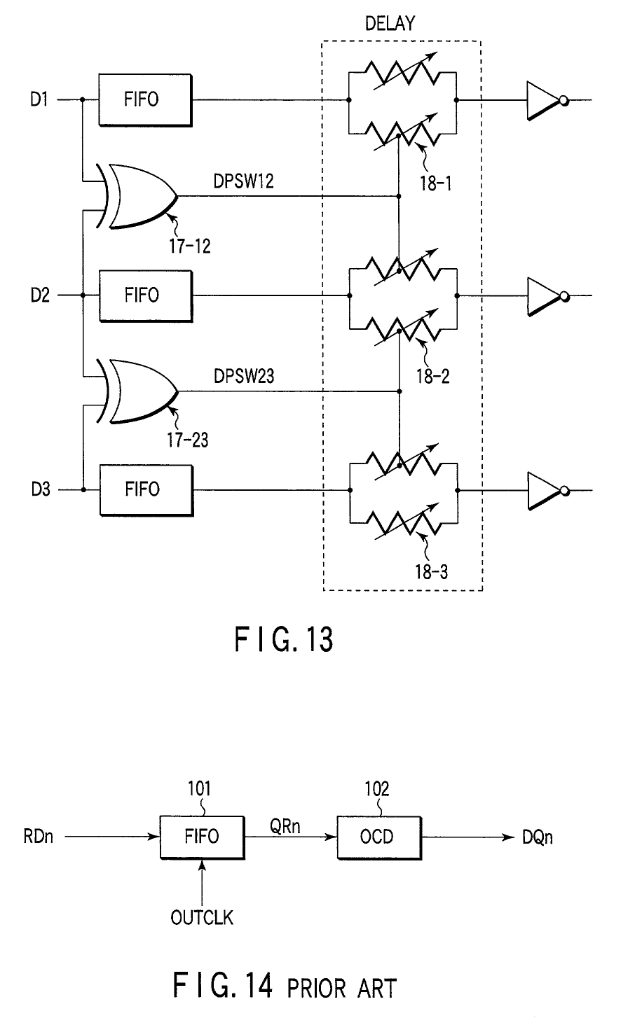

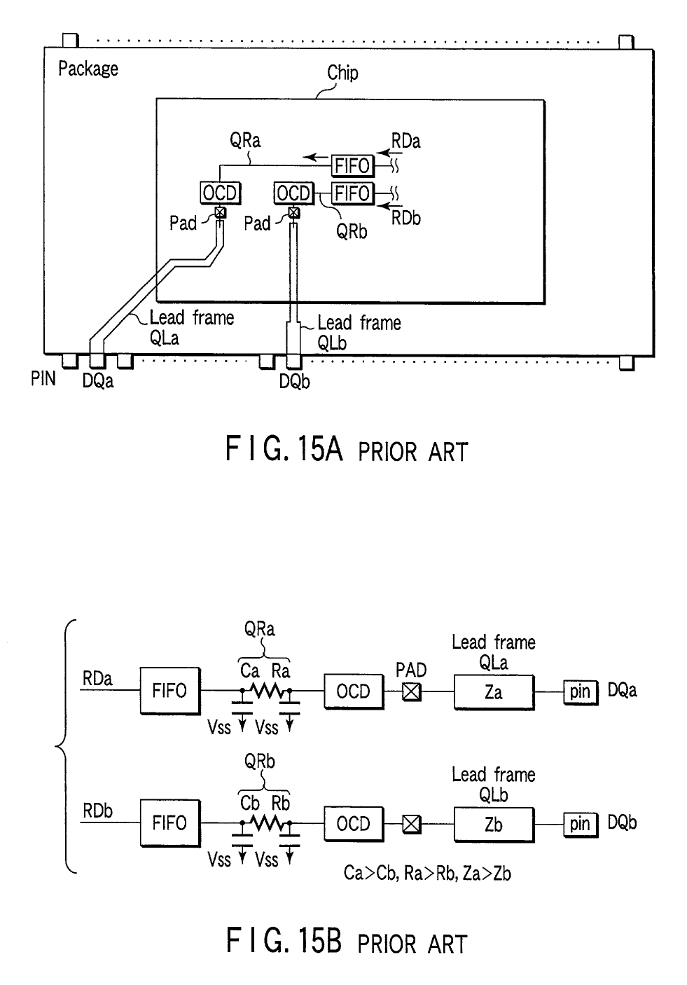

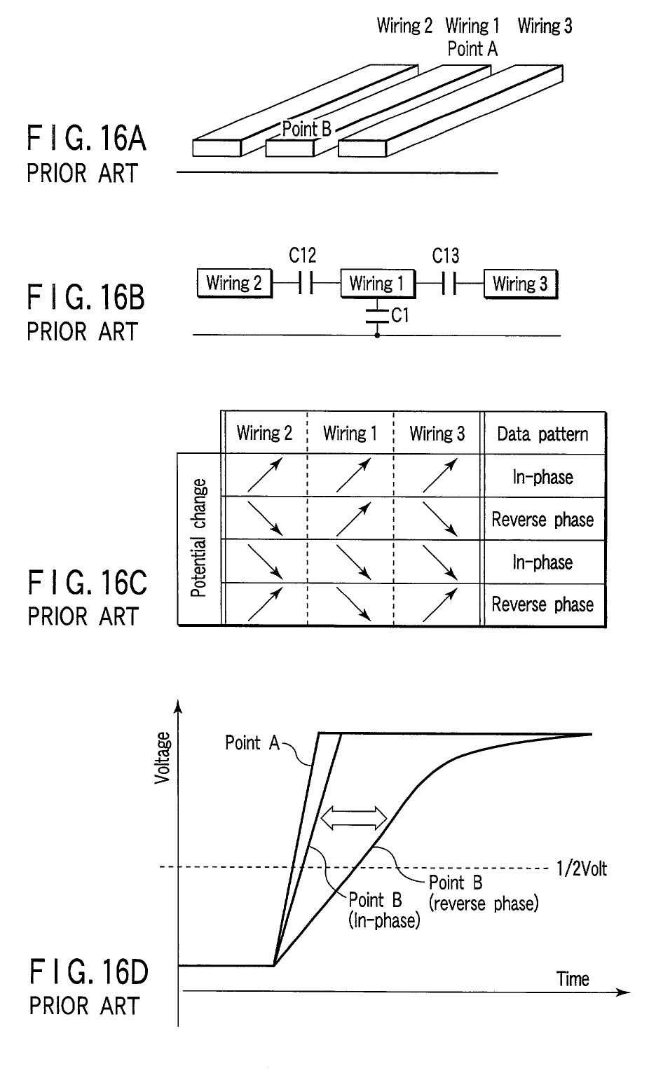

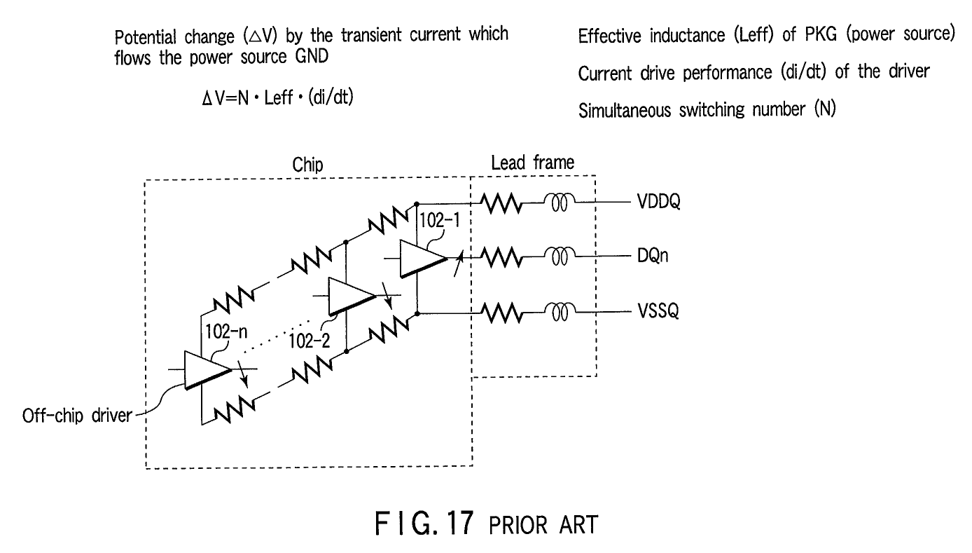

FIG. 12 is a block diagram showing a basic structure of a read path in a semiconductor chip according to a second embodiment of the present invention.

As shown in FIG. 12, the point in which the second embodiment is different from the first embodiment is that the clock OUTCLK for the read data output is delayed than the DELAY 15 in accordance with data pattern.

Specifically, the clock OUTCLK for the read data output is input in the DELAY 15 (15-1) to (5-n). The DELAY 15 delays the clock OUTCLK according to the delay adjustment signal DPSW (DPSW1 to DPSWn). The delay 15 can be constituted with the same circuit as the above DELAY's 12 and 12′. The delay adjustment signal DPSW is output from the DEC 16.

The DEC 16 decodes the n bit read data RD (RD1 to RDn) read from the memory cell not shown to output the delay adjustment signal DPSW. The DEC 16 is also constituted with the same circuit as the above DEC 13, 13′ and 13″ or the like.

The above n bit read data RD (RD1 to RDn) are input to the FIFO 11 respectively. FIFO 11 operates in synchronization with the clock OUTCLK (OUTCLK1 to OUTCLKn) which is delayed and adjusted. When the clock OUTCLK which is delayed and adjusted change the “HIGH” level, for example, the input read data RD is output as the data QR (QR1 to QRn). The data QR is input the OCD14.

The OCD 14 outputs the input data QR as data DQ (DQ1 to DQn) to the external pin via the pad (not shown) and the lead frame (not shown).

These FIFO 11 and the OCD 14 can be constituted with the same circuit as the circuit explained in the first embodiment.

In such device according to the second embodiment, it is possible to alleviate the disparity in the access time resulting from the data pattern.

Third Embodiment

FIG. 13 is a block diagram showing a basic structure of a read path in the semiconductor memory chip according to the third embodiment of the present invention.

As shown in FIG. 13, the point in which the third embodiment is different in particular from the first and the second embodiment is that the read data transmitted to the adjacent data lines D1 and D2, and D2 and D3 is decoded with the DEC 17 (17-12 and 17-23) with the result that the delay adjustment signal DPSW12/23 is created. The DEC 17 comprises, for example, an exclusive or circuit (hereinafter referred to as EXOR). The delay adjustment signal DPSW 12 is input to the DELAY 18-1 and DELAY 18-2 provided on the data lines D1 and D2 while the delay adjustment signal DPSW23 is input to the DELAY 18-2 and DELAY 18-3 provided on the data lines D2 and D3.

Incidentally, suppose that the potential level of the data lines D1 and D2 are changed mutually in the same in-phase. At this time, the delay adjustment signal DPSW 12 is set to the “HIGH” level. On the other hand, when the potential level is changed mutually in the reverse phase, the delay adjustment signal DPSW 12 is set to the “LOW” level.

Furthermore, suppose that the potential level of the data lines D2 and D3 change mutually in the in-phase. At this time, the delay adjustment signal DPSW 23 is set to the “HIGH” level. On the other hand, when the potential level changes mutually in the reverse phase, the delay adjustment signal DPSW 23 is set to the “LOW” level.

When the case of the data line D2 is explained, the delay of the DELAY 18-2 by the delay adjustment signal DPSW12/23 is set as follows.

(1) In the case of DPSW 12=DPSW 23=“HIGH”, the delay is set to be maximum.

(2) In the case of DPSW 12=DPSW 23=“LOW”, the delay is set to be minimum.

(3) In the case of DPSW 12=DPSW 23=“LOW”, or in the case of the reverse thereof, the delay is set to be a midway between the maximum and minimum.

With respect to the data lines D1 and D3, in the same manner as the data line D2, the state of the data line located adjacent to each other is decoded to make a delay adjustment.

Furthermore, there is illustrated a case in which three data lines are provided. Even when four or more data lines are provided, the third embodiment can be applied effectively.

In the device according to the third embodiment, in the same manner as the first and the second embodiment, it is possible to alleviate the disparity in the access time resulting from the data pattern.

As has been explained above, the present invention has been explained from the first to the third embodiment. However, the present invention is not limited thereto. In the practice of the invention, it is possible to modify the present invention in various ways within the scope of not departing from the gist of the present invention.

For example, in the above first to third embodiments, there has been explained a case in which the present invention has been applied to the case of the lead path in the semiconductor memory chip. A main object of the present invention is to alleviate the disparity in the access time resulting from the data pattern. As a consequence, the data which is delay adjusted in accordance with the data pattern is not limited only to the read data. For example, the data may be write data which is written into the memory cell, and the data may be an address signal for designating the address of the memory cell.

For example, when the data is write data, the OCD 14 may be changed to the write buffer circuit. When the data is an address signal, the above OCD 14 may be changed to the address buffer circuit.

The embodiments described above are semiconductor memories. Examples of the semiconductor memories are a DRAM, a flash EEPROM, and the like.

The advantage of the invention is more as the number of signals simultaneously output increases to ×4 bits, ×8 bits, ×16 bits, and so fourth. In view of this, the present invention is particularly useful when applied to semiconductor integrated circuits that output ×16 bits or more at a time.

Furthermore, it goes without saying that the above embodiment can be practiced in a single manner or in an appropriate combination thereof.

Furthermore, each of the above embodiments includes inventions at various stages, and it is possible to extract inventions at various stages with an appropriate combination of a plurality of constituent elements disclosed in each of the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit device comprising:
a register circuit which receives a data signal, an output timing of the register circuit being controlled by a clock signal;
a delay adjustment circuit which receives an output of the register circuit, a delay time of the delay adjustment circuit being adjusted by a delay adjustment signal based on the data signal; and
a driver circuit which receives an output of the delay adjustment circuit.

2. The device according to claim 1, wherein the data signal is a read data signal, and the driver circuit is an off-chip driver circuit.

3. The device according to claim 1, wherein the data signal is a write data signal, and the driver circuit is a write data buffer circuit.

4. The device according to claim 1, wherein the data signal is an address signal, and the driver circuit is an address buffer circuit.

5. A semiconductor integrated circuit device comprising:
a delay adjustment circuit which receives a clock signal, a delay time of the delay adjustment circuit being adjusted by a delay adjustment signal based on a data signal;
a register circuit which receives the data signal, an output timing of the register circuit being controlled by a clock signal which is delay adjusted in the delay adjustment circuit; and
a driver circuit which receives an output of the register circuit.

6. The device according to claim 5, wherein the clock signal is a clock to output a read data, the data signal is a read data signal, and the driver circuit is an off-chip driver circuit.

7. A semiconductor integrated circuit device comprising:
register circuits which receive data signals, an output timing of each of the register circuits being controlled by a clock signal;
delay adjustment circuits which receive outputs of the register circuits, a delay time of each of the delay adjustment circuits being adjusted by a delay adjustment signal based on the data signals adjacent to each other; and
driver circuits which receive outputs of the delay adjustment circuits.

8. The device according to claim 7, wherein the data signals are read data signals, and the driver circuits are off-chip driver circuits.

9. The device according to claim 7, wherein the data signals are write data signals, and the driver circuits are write data buffer circuits.

10. The device according to claim 7, wherein the data signals are address signals, and the driver circuits are address buffer circuits.
